(19) United States
(12) Patent Application Publication
(10) Pub. No.: US 2025/0029912 A1
(43) Pub. Date: Jan. 23, 2025

(54) ENHANCED INTERCONNECTION BALL GRID ARRAY DESIGN, SEMICONDUCTOR STRUCTURE, AND FABRICATING METHOD THEREOF

(71) Applicant: YANGTZE MEMORY TECHNOLOGIES CO., LTD., Wuhan (CN)

(72) Inventors: Shanshan Zhao, Wuhan (CN); Baohua Zhang, Wuhan (CN); Li Tao, Wuhan (CN)

(21) Appl. No.: 18/234,335

(22) Filed: Aug. 15, 2023

Related U.S. Application Data
(63) Continuation of application No. PCT/CN2023/108623, filed on Jul. 21, 2023.

(51) Int. Cl. H01L 23/498; H01L 21/48

(52) U.S. Cl. CPC H01L 23/49838; H01L 21/4853; H01L 23/49816; H01L 23/49866

(57) ABSTRACT

A semiconductor structure, a fabricating method thereof, and a chip packing structure are provided. The disclosed semiconductor structure includes a printed circuit board, a chip packing structure, and a ball grid array connected between the printed circuit board and the chip packing structure. The ball grid array includes first solder balls each having a first lateral size, and second solder balls each having a second lateral size greater than the first lateral size. The second solder balls are located at corners of the ball grid array, respectively.

### CROSS-REFERENCE TO RELATED APPLICATIONS

This application is a continuation of International Application No. PCT/CN2023/108623, filed on Jul. 21, 2023, entitled “ENHANCED INTERCONNECTION BALL GRID ARRAY DESIGN, SEMICONDUCTOR STRUCTURE, AND FABRICATING METHOD THEREOF,” which is incorporated herein by reference in its entirety.

### TECHNICAL FIELD

The present disclosure generally relates to the field of semiconductor technology, and more particularly, to enhanced interconnection ball grid array designs, related semiconductor structures, and fabricating methods thereof.

### BACKGROUND

When a semiconductor package with a ball grid array (BGA) is attached on a printed circuit board (PCB), warping problems on different parts of the structure may occur due to the differences in the coefficients of thermal expansion (CTE) of different materials of different parts of the structure. Both the PCB and the semiconductor package may suffer wrapping and deformation problems during the operation when there are changes of the working environmental temperature, and resulting the solder balls to crack or break. The failure of the mechanical connection of the BGA can cause a short circuit or open circuit of the semiconductor device, such that the semiconductor device cannot work normally.

### BRIEF SUMMARY

Implementations of semiconductor structures and fabricating methods thereof are described in the present disclosure.

One aspect of the present disclosure provides a semiconductor structure, comprising: a printed circuit board; a chip packing structure; and a ball grid array connected between the printed circuit board and the chip packing structure, the ball grid array comprising: first solder balls each having a first lateral size, and second solder balls each having a second lateral size greater than the first lateral size, wherein the second solder balls are located at corners of the ball grid array, respectively.

In some implementations, each second solder ball occupies at least a corner position of the ball grid array and laterally extends along a diagonal direction of the ball grid array.

In some implementations, each second solder ball occupies at least a corner position of the ball grid array, and comprises: a first portion laterally extending along a first direction along a row of the ball grid array; and a second portion laterally extending along a second direction along a column of the ball grid array.

In some implementations, each second solder ball partially surrounds a corner first solder ball of the ball grid array, and comprises: a first portion laterally extending along a first direction along a row of the ball grid array; and a second portion laterally extending along a second direction along a column of the ball grid array.

In some implementations, the first solder balls are electrically connected between the printed circuit board and the chip packing structure; and the second solder balls are electrically disconnected with the printed circuit board or the chip packing structure.

In some implementations, the chip packing structure comprises: a substrate; at least one chip attached on a first surface of the substrate; a conductive wiring structure embedded in the substrate and electrically connected with the at least one chip, wherein the ball grid array is attached to a second surface of the substrate opposite to a first side, the first solder balls are electrically connected to the conductive wiring structure, and the second solder balls are electrically disconnected with the conductive wiring structure.

In some implementations, the chip packing structure further comprises: an array of ball pads on the second surface of the substrate, comprising: first ball pads each having a first area and electrically connected to the conductive wiring structure, and second ball pads each having a second area and electrically disconnected to the conductive wiring structure, wherein the first area is less than the second area.

In some implementations, a first material of the first solder balls is different from a second material of the second solder balls.

In some implementations, the first material has a first mechanical strength and a first thermal expansion coefficient; and the second material has a second mechanical strength greater than the first mechanical strength and a second thermal expansion coefficient less than the first thermal expansion coefficient.

Another aspect of the present disclosure provides a method of forming a semiconductor structure, comprising: providing a chip packing structure, comprising: attaching at least one chip on a first surface of a substrate, and forming a ball grid array on a second surface of the substrate, the ball grid array comprising: first solder balls each having a first lateral size, and second solder balls each having a second lateral size greater than the first lateral size, wherein the second solder balls are located at corners of the ball grid array, respectively; and attaching the chip packing structure to a printed circuit board, such that the ball grid array are connected between the chip packing structure and the printed circuit board.

In some implementations, providing the chip packing structure comprises: forming a conductive wiring structure embedded in the substrate; and forming an array of ball pads on the second surface of the substrate, comprising: first ball pads each having a first area and electrically connected to the conductive wiring structure, and second ball pads each having a second area and electrically disconnected to the conductive wiring structure, wherein the first area is less than the second area.

In some implementations, providing the chip packing structure further comprises: attaching the at least one chip attached on the first surface of the substrate; wiring the at least one chip to the conductive wiring structure; forming the ball grid array on the array of ball pads, comprising: forming the first solder balls on the first ball pads, respectively; and forming the second solder balls on the second ball pads, respectively.

In some implementations, the first solder balls and the second solder balls are formed simultaneously in a same process.

In some implementations, the method further comprises: forming an array of ball openings in a mounting region of the printed circuit board, comprising: first ball openings each having a third area and exposing a contact pad electrically connected to a circuit of the printed circuit board, and second ball openings each having a fourth area greater than the third area, wherein the second ball openings are located at corners of the mounting region, respectively.

In some implementations, attaching the chip packing structure to the printed circuit board comprising: aligning the chip packing structure to the mounting region of the printed circuit board; attaching the chip packing structure to the mounting region of the printed circuit board, such that each first solder ball is located in a corresponding first ball opening, and each second solder ball is located in a corresponding second ball opening; and sequentially heating and cooling the ball grid array, such that the chip packing structure is mechanically connected to the printed circuit board through the first solder balls and second solder balls.

Another aspect of the present disclosure provides a chip packing structure, comprising: a substrate; at least one chip attached on a first surface of the substrate; a conductive wiring structure embedded in the substrate and electrically connected with the at least one chip; and an array of ball pads on a second surface of the substrate opposite to the first surface, the array of ball pads comprising: first ball pads each having a first area, and second ball pads each having a second area greater than the first area, wherein the second ball pads are located at corners of the array of ball pads, respectively.

In some implementations, each second ball pad occupies at least a corner position of the array of ball pads and laterally extends along a diagonal direction of the array of ball pads.

In some implementations, each second ball pad occupies at least a corner position of the array of ball pads, and comprises: a first portion laterally extending along a first direction along a row of the array of ball pads; and a second portion laterally extending along a second direction along a column of the array of ball pads.

In some implementations, each second ball pad partially surrounds a corner first ball pad of the array of ball pads, and comprises: a first portion laterally extending along a first direction along a row of the array of ball pads; and a second portion laterally extending along a second direction along a column of the array of ball pads.

In some implementations, the first ball pads are electrically connected to the at least one chip through the conductive wiring structure; and the second ball pads are electrically disconnected with the at least one chip and the conductive wiring structure.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic diagram in a perspective side view of a semiconductor structure, in accordance with some implementations of the present disclosure.

FIG. 2A illustrates a schematic diagram in a top view of a ball grid array, in accordance with some implementations of the present disclosure.

FIG. 2B illustrates a schematic diagram in a top view of another ball grid array, in accordance with some other implementations of the present disclosure.

FIG. 2C illustrates a schematic diagram in a top view of another ball grid array, in accordance with some other implementations of the present disclosure.

FIG. 3 illustrates a flow diagram of a method for forming a semiconductor structure, in accordance with some implementations of the present disclosure.

FIG. 4 illustrates a schematic diagram in a perspective side view of a semiconductor structure at certain fabricating step of the method shown in FIG. 3, in accordance with some implementations of the present disclosure.

FIG. 5A illustrates a schematic diagram in a top view of a semiconductor structure at certain fabricating step of the method shown in FIG. 3, in accordance with some implementations of the present disclosure.

FIG. 5B illustrates a schematic diagram in a top view of another semiconductor structure at certain fabricating step of the method shown in FIG. 3, in accordance with some other implementations of the present disclosure.

FIG. 5C illustrates a schematic diagram in a top view of another semiconductor structure at certain fabricating step of the method shown in FIG. 3, in accordance with some other implementations of the present disclosure.

FIG. 6 illustrates a schematic diagram in a perspective side view of a semiconductor structure at certain fabricating step of the method shown in FIG. 3, in accordance with some implementations of the present disclosure.

FIG. 7A illustrates a schematic diagram in a top view of a semiconductor structure at certain fabricating step of the method shown in FIG. 3, in accordance with some implementations of the present disclosure.

FIG. 7B illustrates a schematic diagram in a top view of another semiconductor structure at certain fabricating step of the method shown in FIG. 3, in accordance with some other implementations of the present disclosure.

FIG. 7C illustrates a schematic diagram in a top view of another semiconductor structure at certain fabricating step of the method shown in FIG. 3, in accordance with some other implementations of the present disclosure.

FIG. 8 illustrates a schematic diagram in a perspective side view of a semiconductor structure at certain fabricating step of the method shown in FIG. 3, in accordance with some implementations of the present disclosure.

FIG. 9A illustrates a schematic diagram in a top view of a semiconductor structure at certain fabricating step of the method shown in FIG. 3, in accordance with some implementations of the present disclosure.

FIG. 9B illustrates a schematic diagram in a top view of another semiconductor structure at certain fabricating step of the method shown in FIG. 3, in accordance with some other implementations of the present disclosure.

FIG. 9C illustrates a schematic diagram in a top view of another semiconductor structure at certain fabricating step of the method shown in FIG. 3, in accordance with some other implementations of the present disclosure.

FIG. 10 illustrates a schematic diagram in a perspective side view of a semiconductor structure at certain fabricating step of the method shown in FIG. 3, in accordance with some implementations of the present disclosure.

FIG. 11 illustrates a schematic diagram in a perspective side view of a semiconductor structure at certain fabricating step of the method shown in FIG. 3, in accordance with some implementations of the present disclosure.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

Implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The front surface of the substrate is typically where a semiconductor device is formed, and therefore the semiconductor device is formed at a top side of the substrate unless stated otherwise. The bottom surface is opposite to the front surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is adjacent to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As described above, when a semiconductor package with a ball grid array (BGA) is attached on a printed circuit board (PCB), warping problems on different parts of the structure may occur due to the differences in the coefficients of thermal expansion (CTE) of different materials of different parts of the structure. Both the PCB and the semiconductor package may suffer wrapping and deformation problems during the operation when there are changes of the working environmental temperature, and resulting the solder balls to crack or break. The failure of the mechanical connection of the BGA can cause a short circuit or open circuit of the semiconductor device, such that the semiconductor device cannot work normally.

To address the above issues, the present disclosure provides a packaging substrate BGA PAD structure design to improve BGA connection strength. Under the premise of meeting the requirements of the package shape, the solder ball structure around the substrate side can be optimized to enhance the mechanical interconnection between the semiconductor device and the PCB, so as to reduce the mechanical interconnection failure of the semiconductor device in the rapid temperature changing environment. Therefore, the semiconductor device can be protected, and the product reliability can be improved.

The disclosed enhanced interconnection ball grid array design does not change the external dimensions of the package. The fabricating process is simple, and does not need to increase the process. Thus, conventional fabricating equipment can be used without increasing the cost of investment. The modular package solution can be adopted, which is conducive to mass production. The disclosed fabricating process can significantly improve product reliability, enhance the mechanical interconnection between semiconductor devices and PCBs, enhance the heat dissipation capability of the package, and improve the product performance.

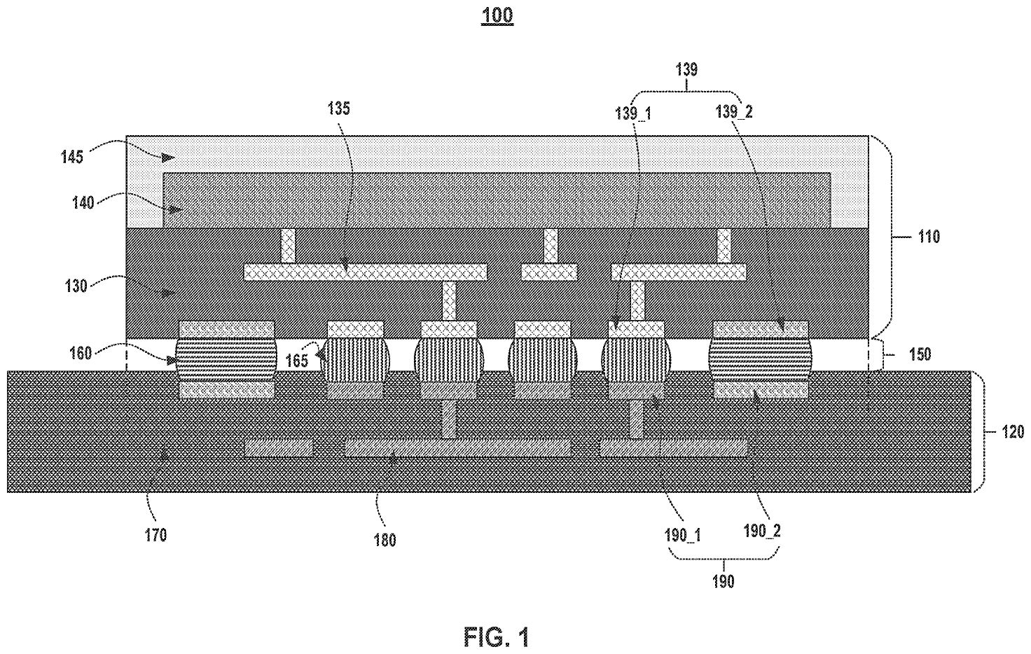

Referring to FIG. 1, a schematic diagram in a perspective side view of an example semiconductor device structure is illustrated, in accordance with some implementations of the present disclosure. As show, the semiconductor device structure 100 can include a chip packing structure 110, a printed circuit board (PCB) 120, and a ball grid array (BGA) 150 connected between the PCB 120 and the chip packing structure 110. It is noted that, the semiconductor device structure 100 can further include any other suitable components that are not shown in FIG. 1.

The chip packing structure 110 can include a base substrate 130, a die/die stack 140, and a mold compound layer 145. The base substrate 130 can be any suitable semiconductor substrate having any suitable structure, such as a monocrystalline single-layer substrate, a polycrystalline silicon (polysilicon) single-layer substrate, a polysilicon and metal multi-layer substrate, etc. The base substrate 130 can include conductive wiring structures 135 embedded therein. The conductive wiring structures 135 can include any suitable conductive interconnection structures, such as conductive vias and patterned conductive layers, etc.

The base substrate 130 can further include an array of ball pads 139 on a bottom surface to accept the BGA 150 for both electrically connections and/or mechanically fasten connections. The array of ball pads 139 can include first ball pads 139_1 each having a first area and electrically connected to the conductive wiring structure 135, and the second ball pads 139_2 each having a second area and electrically disconnected to the conductive wiring structure 139. In some implementations, the first area is less than the second area.

The conductive wiring structures 135 and the array of ball pads 139 can include any suitable conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art. In some implementations, the second ball pads 139_2 can comprise materials different from the materials of the first ball pads 139_1. For example, the first ball pads 139_1 can comprise conductive materials, while the second ball pads 139_2 can comprise dielectric materials.

The die/die stack 140 can be attached to the base substrate 130 by an adhesive film (not shown). In some implementations, the die/die stack 140 can be any suitable semiconductor die/die stack including one or more semiconductor chips. The adhesive film can be any suitable die attach film (DAF). In some implementations, a plurality of bond pads (not shown, also being referred as contact pads, redistribution pads, or similar structures as known to those skilled in the art) can be located on the die/die stack 140. In some implementations, a plurality of signal wires (not shown) can be electrically connected between the plurality of bond pads of the die/die stack 140 and the conductive wiring structures 135.

The chip packing structure 110 can further include a mold compound layer 145 on the base substrate 130 to fully cover the die/die stack 140 and the plurality of signal wires. In some implementations, the mold compound layer 145 can be a thermally curable epoxy mold compound or a thermally curable epoxy mold resin. For example, the mold compound layer 145 comprises an inorganic filler (for example, silica), an epoxy resin, a curing agent, a flame retardant, a curing promoter, a release agent, and any other suitable components as known to those skilled in the art.

The PCB 120 can include a laminated sandwich structure of conductive layers 180 and insulating layers. Each of the conductive layers 180 can be designed with a pattern of traces, planes and other features (similar to wires on a flat surface) etched from one or more conductive sheet layers laminated onto and/or between sheet layers of a non-conductive substrate 170.

The PCB 120 can further include an array of contact pads 190 on the top surface in the shape designed to accept the chip packing structure 110's terminals, such as BGA 150, to both electrically connect and/or mechanically fasten the chip packing structure 110 to the PCB 120. The array of contact pads 190 can include first contact pads 190_1 each having a first area and electrically connected to the conductive layers 180, and second contact pads 190_2 each having a second area and electrically disconnected to the conductive layers 180. In some implementations, the first area is less than the second area.

In some implementations, the PCB 120 can further include vias (not shown), such as plated-through holes that allow interconnections between layers. The conductive layers 180, contact pads 190 and vias can be formed by using any suitable conductive materials, such as Cu, Ni, Au, Ag, Pt, Co, Ti, Cr, Zr, Mo, Ru, Hf, W, Re, graphite, carbon black, or any suitable combinations thereof. In some implementations, the second contact pads 190_2 can comprise materials different from the materials of the first contact pads 190_1. For example, the first contact pads 190_1 can comprise conductive materials, while the second contact pads 190_2 can comprise dielectric materials.

In some implementations, the ball grid array (BGA) 150 can include a plurality of solder balls 160/165 sandwiched between the bottom surface of the base substrate 130 and the top surface of PCB 120. BGA 150 can include first solder balls 165 electrically and mechanically connected between the first ball pads 139_1 and the first contact pads 190_1, and second solder balls mechanically connected between the second ball pads 139_2 and the second contact pads 190_2. That is, the first solder balls 165 are electrically connected between the PCB 120 and the chip packing structure 110 to provide transmission of electric signals between a circuit on the PCB 120 and a chip 140 on the chip packing structure 110. The second solder balls 160 can be electrically disconnected with the PCB 120 or the chip packing structure 110, and configured for providing mechanical connection support. In some implementations, a first lateral size of each first solder ball 165 is less than a second lateral size of each second solder ball 160.

In some implementations, the first solder balls 165 and the second solder balls 160 can comprise same materials, and can be formed in a same process. For example, the first solder balls 165 and the second solder balls 160 can comprise any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur(S), Zinc (Zn), Germanium (Ge), etc., and any suitable alloy thereof. In some other implementations, the first solder balls 165 and the second solder balls 160 can comprise different materials. For example, the second solder balls 160 can include a material with a high mechanical strength and a low thermal expansion coefficient.

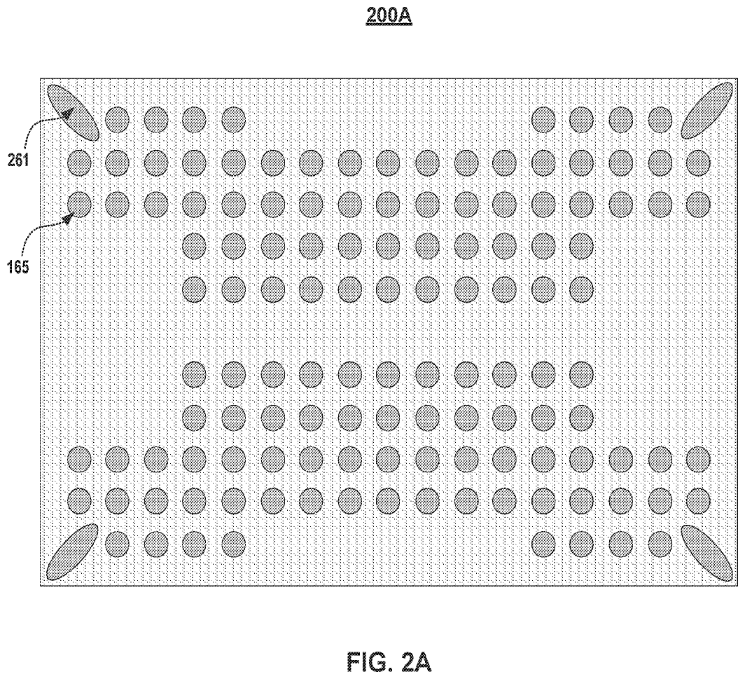

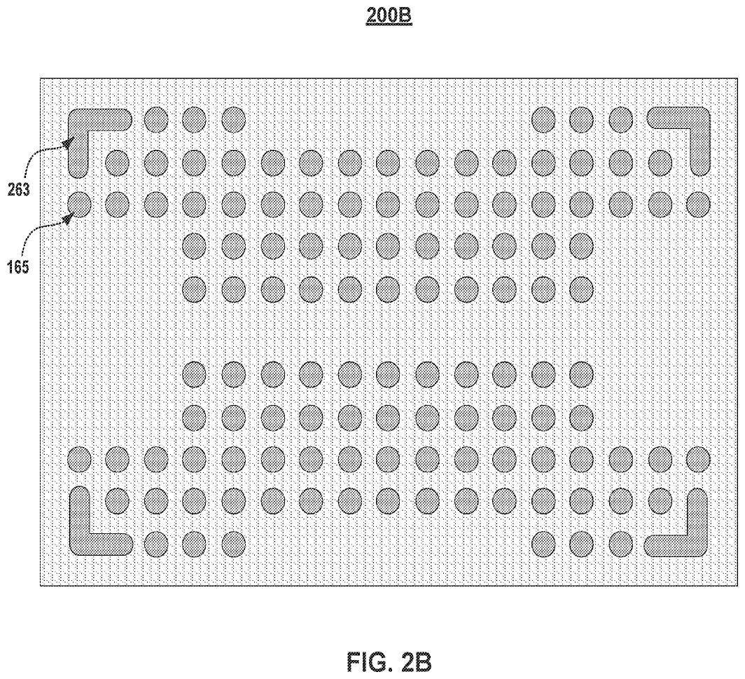

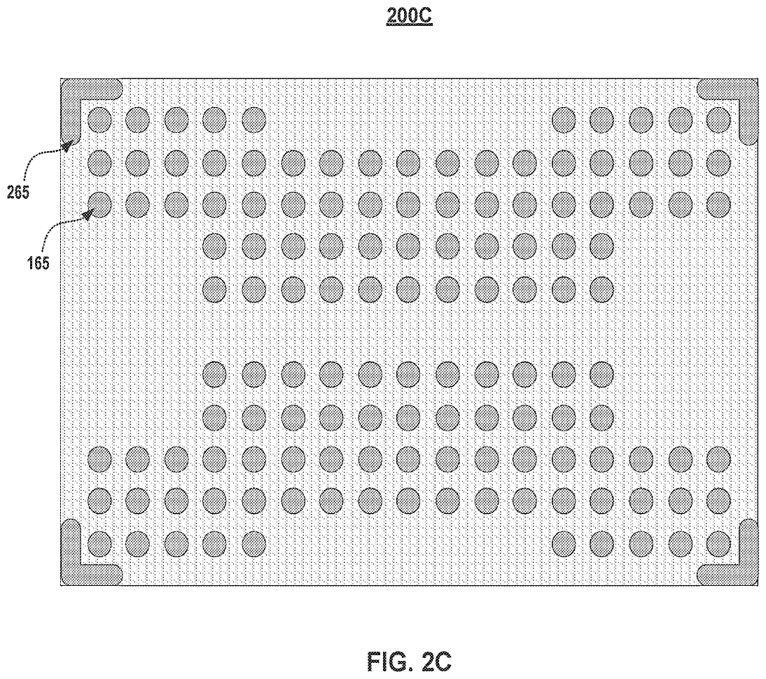

FIGS. 2A-2C illustrate schematic diagrams in a top view of various designs of BGAs 200A, 200B, and 200C, respectively, in accordance with various implementations of the present disclosure.

In some implementations as shown in FIG. 2A, each first solder ball 165 can have an approximate circular shape in a lateral plane, and each second solder ball 261 can have an approximate oval shape in the lateral plane. The second solder balls 261 can be located at corners of the BGA 200A, respectively. Each second solder ball 261 can occupy at least a corner position of the BGA 200A and laterally extends along a diagonal direction of the BGA 200A.

In some other implementations as shown in FIG. 2B, each second solder ball 263 also occupies at least a corner position of the BGA 200B, and are formed by connecting three adjacent first solder balls 165 at the corner position of the BGA 200B. Thus, each second solder ball 263 comprises a first portion laterally extending along a first direction along a row of the BGA 200B, and a second portion laterally extending along a second direction along a column of the BGA 200B.

In some other implementations as shown in FIG. 2C, each second solder ball 265 partially surrounds a corner first solder ball 165 of the BGA 200C. Each second solder ball 265 comprises a first portion laterally extending along a first direction along a row of the BGA 200C, and a second portion laterally extending along a second direction along a column of the BGA 200C.

The disclosed enhanced interconnection ball grid array designs and related semiconductor structures can optimize the solder ball structure at the peripheral sides of the base substrate, and increase the mechanical strength of the interconnection ball structures to enhance the mechanical interconnections between chip packing structure 110 to the PCB 120. Therefore, the mechanical interconnection failure of the semiconductor device in rapid temperature-changing environment can be reduced, the surface mount technology (SMT) yield rate can be increased, and the heat dissipation capability of the products can be improved.

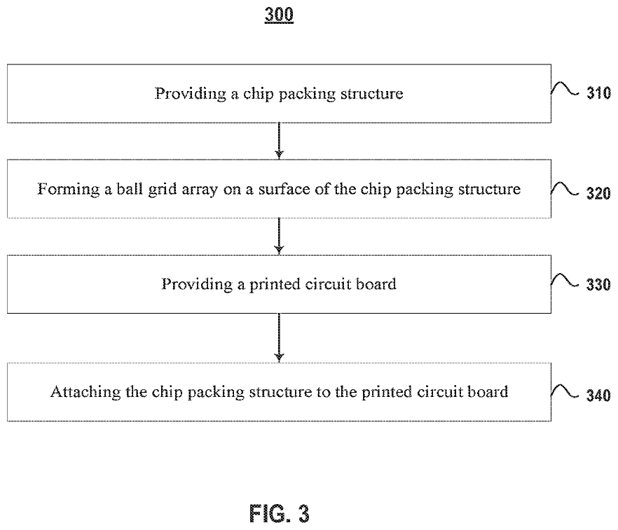

Referring to FIG. 3, a flow diagram of a method for forming an electromagnetic interference shielding package structure is illustrated in accordance with some implementations of the present disclosure. It should be understood that the operations and/or steps shown in FIG. 3 are not exhaustive and that other operations can be performed as well before, after, or between any of the illustrated operations.

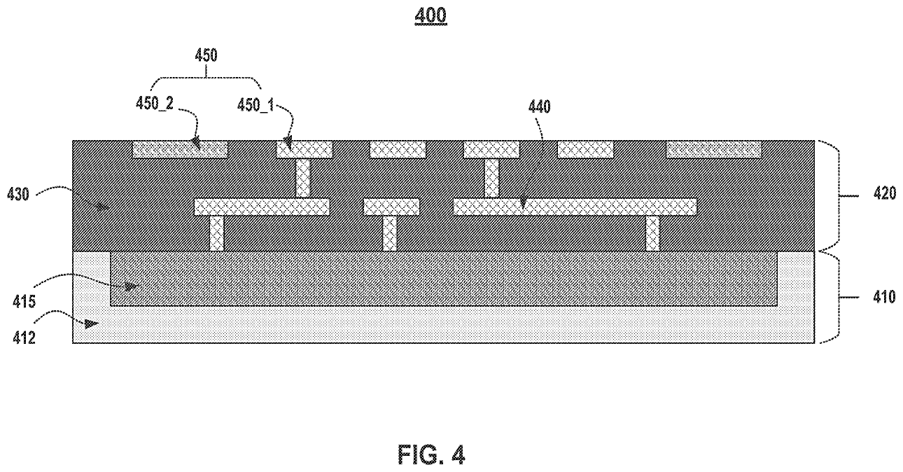

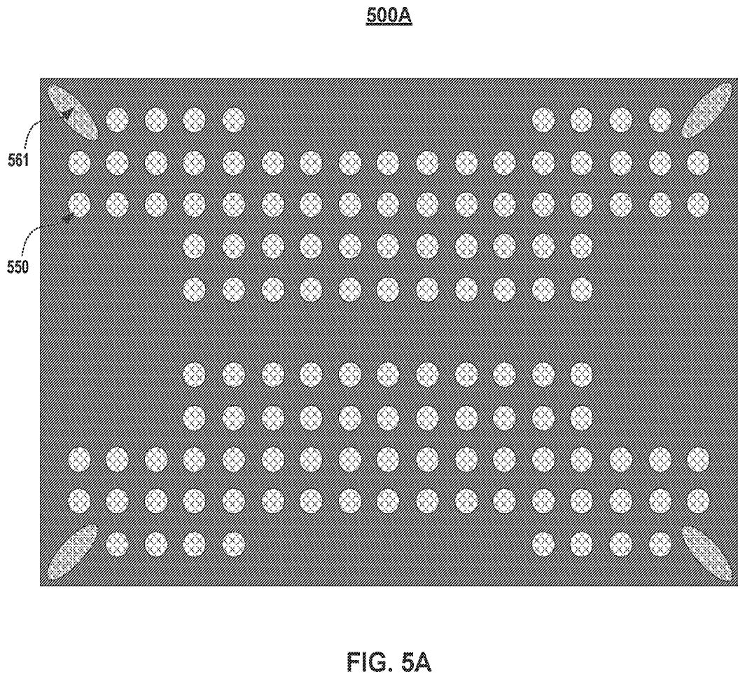

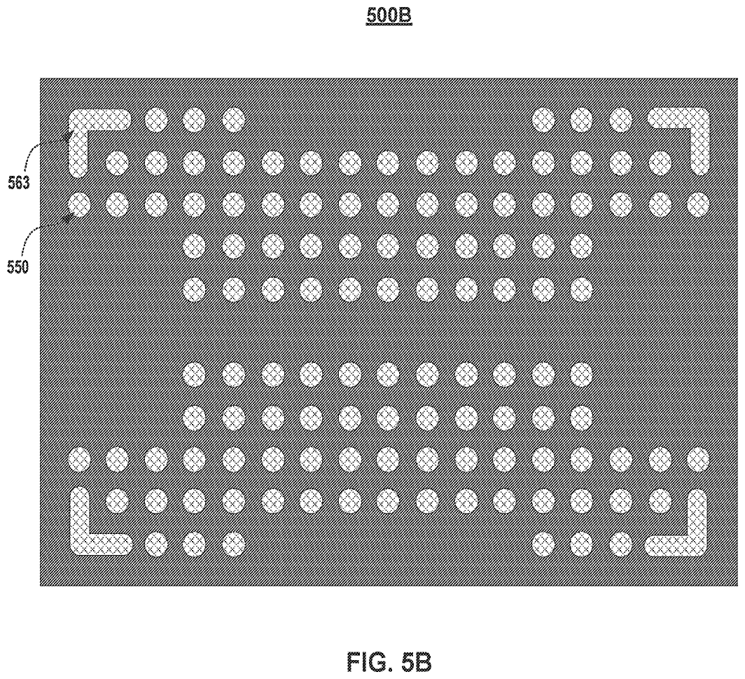

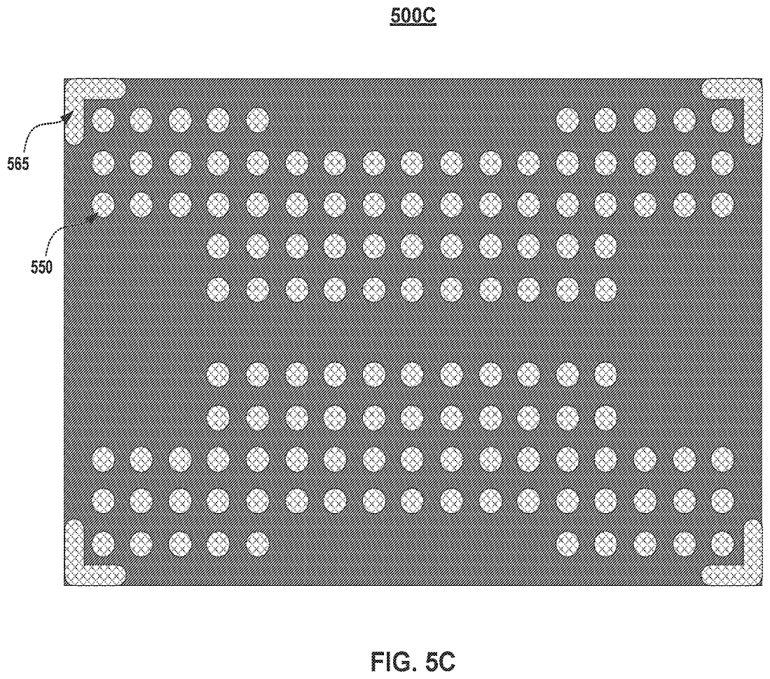

As shown in FIG. 3, the method 300 starts at operation 310, in which a chip packing structure can be provided. FIG. 4 illustrates a schematic diagram in a perspective side view of a semiconductor structure 400 after operation 310 of the method 300 shown in FIG. 3, in accordance with some implementations of the present disclosure. FIGS. 5A-5C illustrate schematic diagrams in a top view of various semiconductor structures after operation 310 of the method 300 shown in FIG. 3, in accordance with some implementations of the present disclosure.

As shown in FIG. 4, in some implementations, operation 310 of providing a chip packing structure comprises forming a base substrate 420. Forming the base substrate 420 includes providing a substrate 430. The substrate 430 can be any suitable semiconductor substrate having any suitable structure, such as a monocrystalline single-layer substrate, a polycrystalline silicon (polysilicon) single-layer substrate, a polysilicon and metal multi-layer substrate, etc.

Forming the base substrate 420 further includes forming a conductive wiring structure 440 embedded in the substrate 430. The conductive wiring structure 440 can include any suitable conductive interconnection structures, such as conductive vias and patterned conductive layers, etc.

Forming the base substrate 420 further includes forming an array of ball pads 450 on a surface of the substrate 430. The array of ball pads 450 can include first ball pads 450_1 each having a first area and electrically connected to the conductive wiring structure 440, and second ball pads 450_2 each having a second area and electrically disconnected to the conductive wiring structure 440. In some implementations, the first area is less than the second area.

The conductive wiring structure 440 and the array of ball pads 450 can include any suitable conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art.

In some implementations, operation 310 of providing a chip packing structure further comprises attaching a die/die stack 415 on a first surface of the base substrate 420 by using any suitable adhering or fastening means known in the art. In some implementations, an adhesive film (not shown), such as a die attach film (DAF), can be attached to a bottom surface of a bottom chip of the die/die stack 415. And then the die/die stack 415 can be permanently attached or secured to the surface of the base substrate another surface of the base substrate 430 away from the array of ball pads 450.

In some implementations, operation 310 of providing a chip packing structure further comprises wiring the at least one chip of the die/die stack 415 to the conductive wiring structure 440. For example, a plurality of signal wires (not shown) can be formed to electrically connect the die/die stack 415 and the base substrate 420. It is noted that, FIG. 4 shows a single die as an example. In this example, the plurality of signal wires are formed to connect a plurality of signal pads (not shown) respectively on the die to the conductive wiring structure 440 of the base substrates 420. In some other implementations not shown in FIG. 4, the die stack can include multiple layers of dies stacked in a vertical direction. In such cases, the plurality of signal wires can include various groups of signal wires connect a plurality of signal pads and/or redistribution pads respectively, on each layer of the die stack.

In some implementations, operation 310 of providing a chip packing structure further comprises forming a mold compound layer 412 on the base substrate 420 to cover the die/die stack 415 and the plurality of signal wires. In some implementations, the mold compound layer 415 can be formed by any suitable materials, such as a thermally curable epoxy mold compound material or a thermally curable epoxy mold resin. For example, the mold compound layer can be formed by using an inorganic filler (e.g., silica), an epoxy resin, a curing agent, a flame retardant, a curing promoter, a release agent, and any other suitable components as known to those skilled in the art.

Referring to FIGS. 5A-5C, schematic diagrams in a top view of various designs of arrays of ball pads 500A, 500B, and 500C are illustrated respectively, in accordance with various implementations of the present disclosure. In some implementations, the arrays of ball pads 500A, 500B, and 500C can be various examples of the array of ball pads 450 shown in FIG. 4.

In some implementations as shown in FIG. 5A, each first ball pad 550 can have an approximate circular shape in a lateral plane, and each second ball pad 561 can have an approximate oval shape in the lateral plane. The second ball pads 561 can be located at corners of the array of ball pads 500A, respectively. Each second ball pad 561 can occupy at least a corner position of the array of ball pads 500A and laterally extends along a diagonal direction of the array of ball pads 500A.

In some other implementations as shown in FIG. 5B, each second ball pad 563 also occupies at least a corner position of the array of ball pads 500B, and are formed by connecting three adjacent first ball pad 550 at the corner position of the array of ball pads 500B. Thus, each second ball pad 563 comprises a first portion laterally extending along a first direction along a row of the array of ball pads 500B, and a second portion laterally extending along a second direction along a column of the array of ball pads 500A.

In some other implementations as shown in FIG. 5C, each second ball pad 565 partially surrounds a corner first ball pad 550 of the array of ball pads 500C. Each second ball pad 565 comprises a first portion laterally extending along a first direction along a row of the array of ball pads 500C, and a second portion laterally extending along a second direction along a column of the array of ball pads 500C.

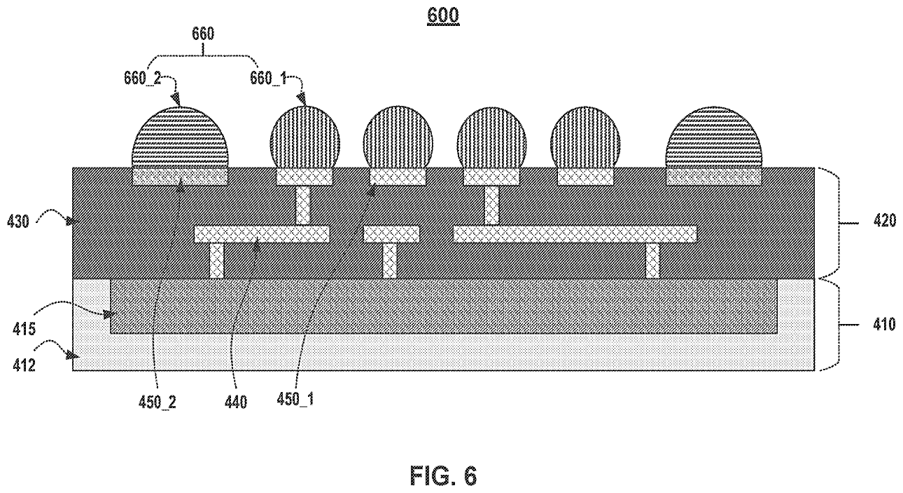

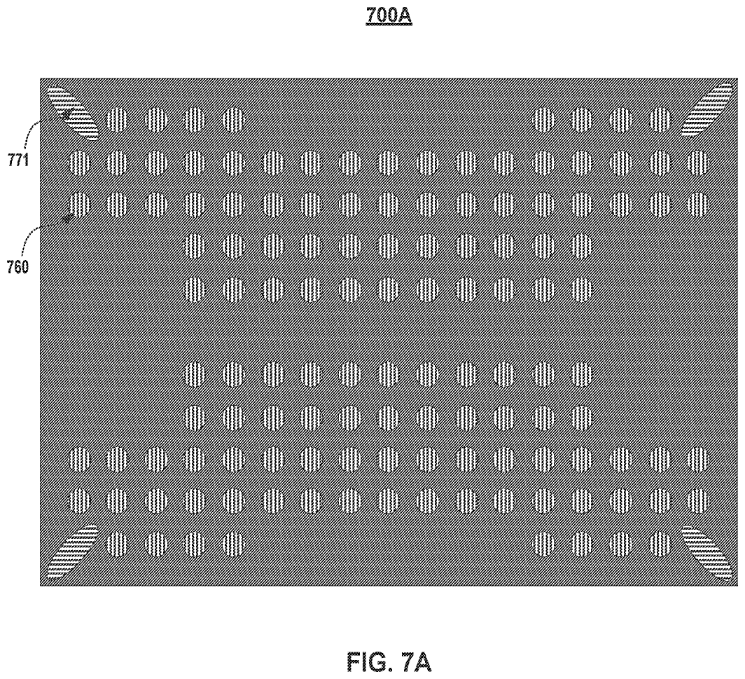

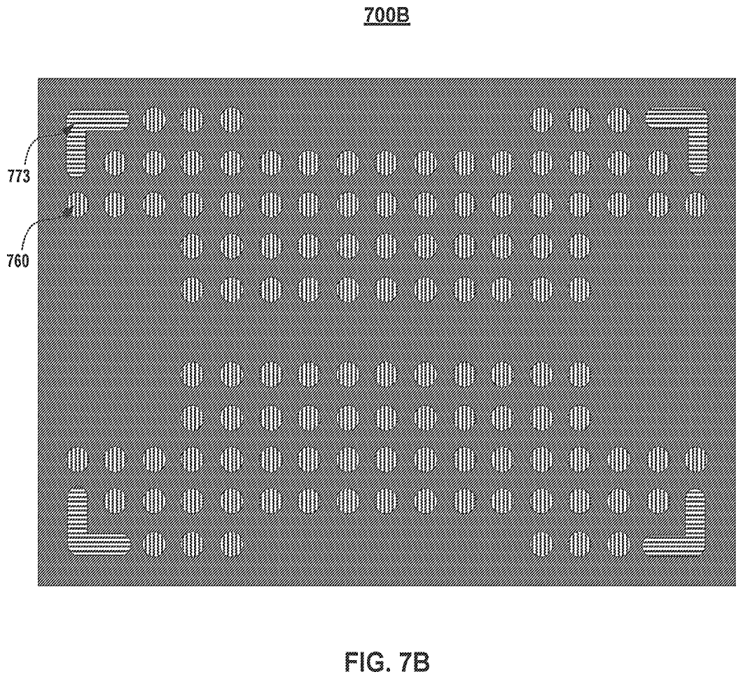

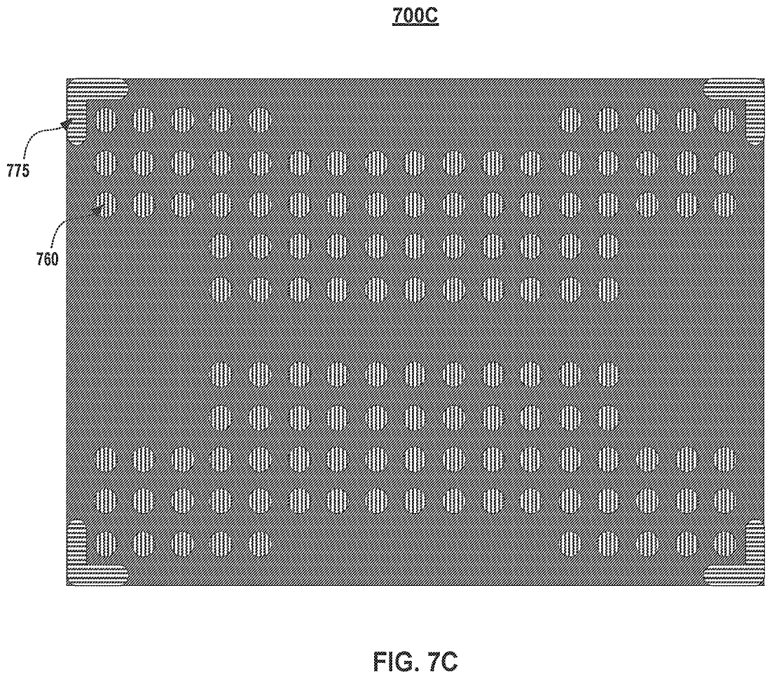

Referring back to FIG. 3, the method 300 can proceed to operation 320, in which a ball grid array (BGA) can be formed on a surface of the chip packing structure. FIG. 6 illustrates a schematic diagram in a perspective side view of a semiconductor structure 600 after operation 320 of the method 300 shown in FIG. 3, in accordance with some implementations of the present disclosure. FIGS. 7A-7C illustrate schematic diagrams in a top view of various semiconductor structures after operation 320 of the method 300 shown in FIG. 3, in accordance with some implementations of the present disclosure.

As shown in FIG. 4, a ball grid array (BAG) 600 can be formed on a second surface of the base substrate 420 opposite to the first surface. The BAG 600 can comprise first solder balls 660_1 each having a first lateral size, and second solder balls 660_2 each having a second lateral size greater than the first lateral size. Each first solder ball 660_1 can be formed on a corresponding first ball pad 450_1, and each second solder ball 660_2 can be formed on a corresponding second ball pad 450_2. That is, the first solder balls 660_1 are electrically connected to the chip packing structure 110 to provide transmission of electric signals. The second solder balls 660_2 can be electrically disconnected with the chip packing structure 110, and configured for providing mechanical connection support only. In some implementations, a first lateral size of each first solder ball 660_1 is less than a second lateral size of each second solder ball 660_2.

In some implementations, the first solder ball 660_1 and the second solder ball 660_2 can be formed using a same material, and can be formed simultaneously in a same process. For example, the first solder ball 660_1 and the second solder ball 660_2 can be formed by comprise any suitable metal material described above. In some other implementations, the first solder balls 660_1 and the second solder balls 660_2 can be formed by using different materials. For example, the second solder balls 660_2 can be formed by using a material with a high mechanical strength and a low thermal expansion coefficient.

Referring to FIGS. 7A-7C, schematic diagrams in a top view of various designs of BGAs 700A, 700B, and 700C are illustrated respectively, in accordance with various implementations of the present disclosure. In some implementations, the BGAs 700A, 700B, and 700C can be various examples of BGA 660 shown in FIG. 6.

In some implementations as shown in FIG. 7A, each first solder ball 760 can have an approximate circular shape in a lateral plane, and each second solder ball 771 can have an approximate oval shape in the lateral plane. The second solder balls 771 can be located at corners of the BGA 700A, respectively. Each second solder ball 771 can occupy at least a corner position of the BGA 700A and laterally extends along a diagonal direction of the BGA 700A.

In some other implementations as shown in FIG. 7B, each second solder ball 773 also occupies at least a corner position of the BGA 700B, and are formed by connecting three adjacent first solder balls 760 at the corner position of the BGA 700B. Thus, each second solder ball 773 comprises a first portion laterally extending along a first direction along a row of the BGA 700B, and a second portion laterally extending along a second direction along a column of the BGA 700B.

In some other implementations as shown in FIG. 7C, each second solder ball 775 partially surrounds a corner first solder ball 760 of the BGA 700C. Each second solder ball 775 comprises a first portion laterally extending along a first direction along a row of the BGA 700C, and a second portion laterally extending along a second direction along a column of the BGA 700C.

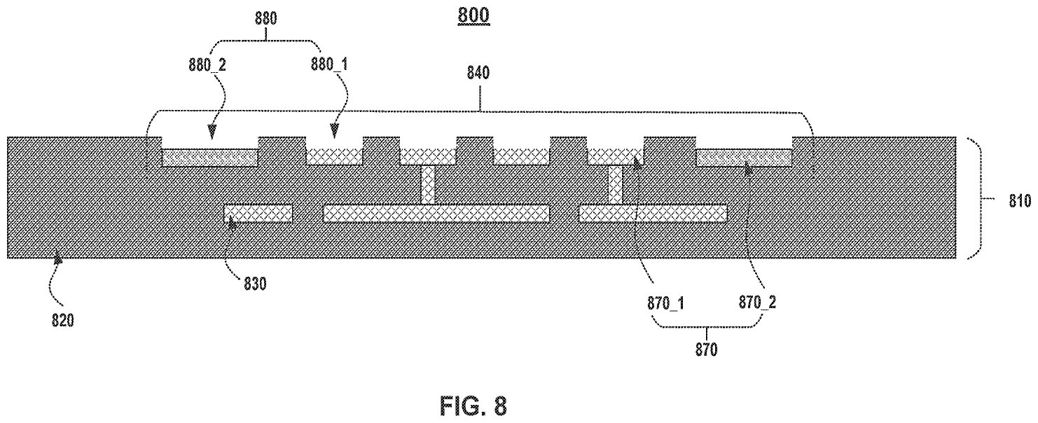

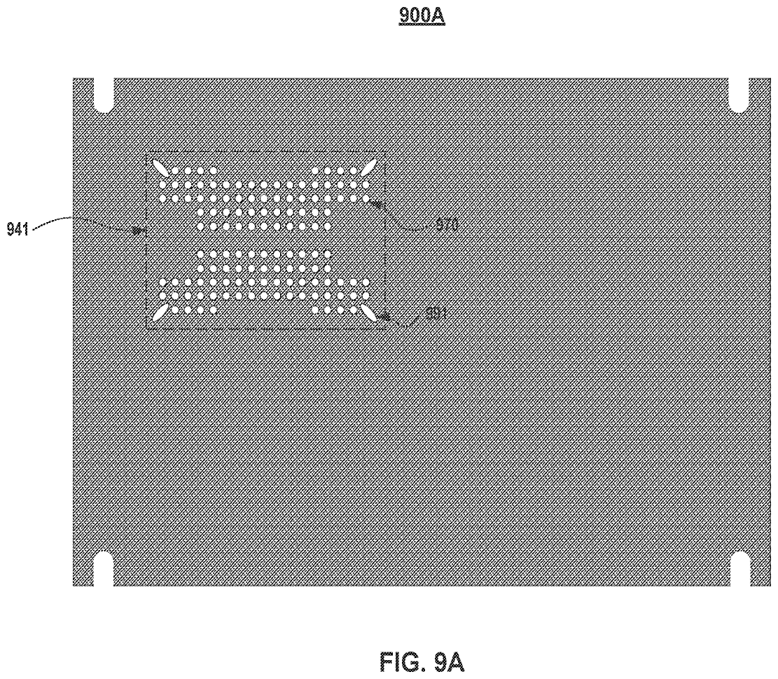

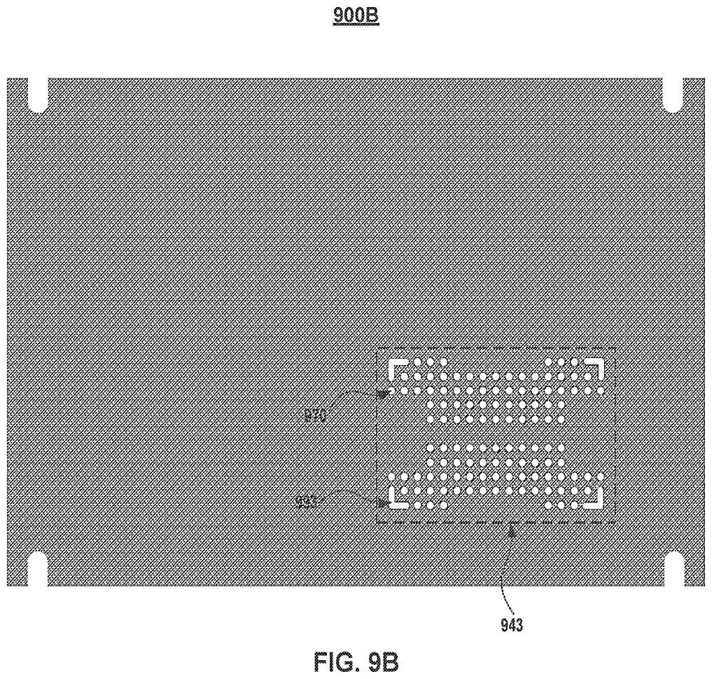

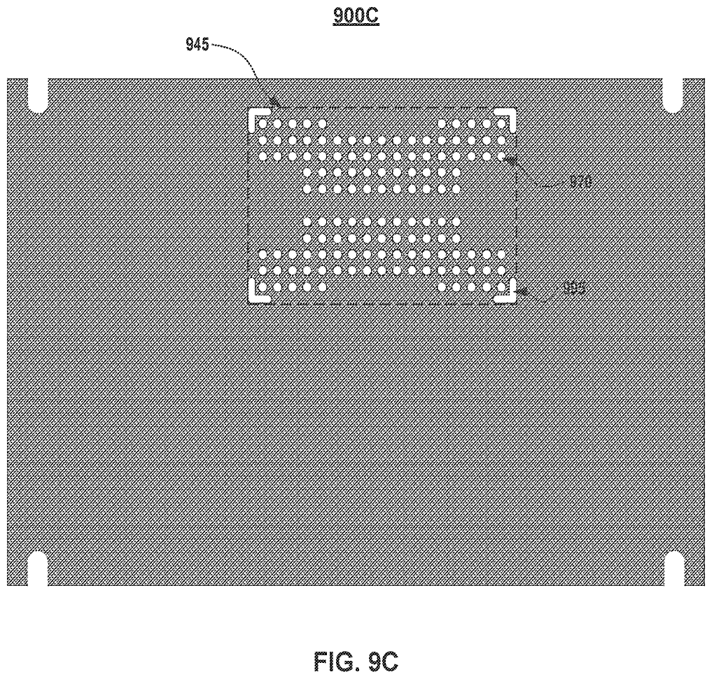

Referring back to FIG. 3, the method 300 can proceed to operation 330, in which a printed circuit board (PCB) can be provided. FIG. 8 illustrates a schematic diagram in a perspective side view of a semiconductor structure 800 after operation 330 of the method 300 shown in FIG. 3, in accordance with some implementations of the present disclosure. FIGS. 9A-9C illustrate schematic diagrams in a top view of various semiconductor structures after operation 330 of the method 300 shown in FIG. 3, in accordance with some implementations of the present disclosure.

As shown in FIG. 8, the operation 330 of providing a PCB 810 can include forming a laminated sandwich structure of conductive layers 830 and insulating layers. Each of the conductive layers 830 can be patterned to form a plurality of of traces, planes and other features (similar to wires on a flat surface) etched from one or more conductive sheet layers laminated onto and/or between sheet layers of a non-conductive substrate 820.

A top conductive layer of the PCB 810 can include an array of contact pads 870 in a mounting region 840. The array of contact pads 870 can include first contact pads 870_1 each having a first area and electrically connected to the conductive layers 830, and second contact pads 870_2 each having a second area and electrically disconnected to the conductive layers 830. In some implementations, the first area is less than the second area.

The conductive layers 830 and contact pads 870 can be formed by using any suitable conductive materials, such as Cu, Ni, Au, Ag, Pt, Co, Ti, Cr, Zr, Mo, Ru, Hf, W, Re, graphite, carbon black, or any suitable combinations thereof. In some implementations, the second contact pads 870_2 can be formed by a material different from a material of forming of the first contact pads 870_1. For example, the first contact pads 870_1 can be formed by using a conductive material, while the second contact pads 870_2 can be formed by using a dielectric material.

As shown in FIG. 8, the operation 330 of providing a PCB 810 can include forming an array of ball openings 880 in a mounting region 840. Each first ball opening 880_1 can have a third area and expose a first contact pad 870_1 electrically connected to a circuit of the PCB. Each second ball opening 880_2 can have a fourth area greater than the third area, and expose a second contact pad 870_2 electrically disconnected to the conductive layers 830 of the PCB 810.

Referring to FIGS. 9A-9C, schematic diagrams in a top view of various designs of PCBs 900A, 900B, and 900C are illustrated respectively, in accordance with various implementations of the present disclosure. In some implementations, the PCBs 900A, 900B, and 900C can be various examples of the PCB 800 shown in FIG. 8. In some implementations, the mounting region 941, 043, and 945 can be various examples of the mounting region 840 shown in FIG. 8.

In some implementations as shown in FIG. 9A, the mounting region 941 can be located in any suitable region of the PCB 900A. Each first contact pad 970 can have an approximate circular shape in a lateral plane, and each second contact pad 991 can have an approximate oval shape in the lateral plane. The second contact pads 991 can be located at corners of the mounting region 941, respectively. Each second contact pad 991 can occupy at least a corner position of the mounting region 941 and laterally extends along a diagonal direction of the array of contact pads.

In some other implementations as shown in FIG. 9B, the mounting region 943 can be located in any suitable region of the PCB 900B. Each second contact pad 993 also occupies at least a corner position of the mounting region 943, and are formed by connecting three adjacent first contact pad 970 at the corner position of the mounting region 943. Thus, each second contact pad 993 comprises a first portion laterally extending along a first direction along a row of the array of contact pads, and a second portion laterally extending along a second direction along a column of the array of contact pads.

In some other implementations as shown in FIG. 9C, the mounting region 945 can be located in any suitable region of the PCB 900C. Each second contact pad 995 partially surrounds a corner first contact pad 970 at a corner of the mounting region 941. Each second contact pad 995 comprises a first portion laterally extending along a first direction along a row of the array of contact pads, and a second portion laterally extending along a second direction along a column of the array of contact pad.

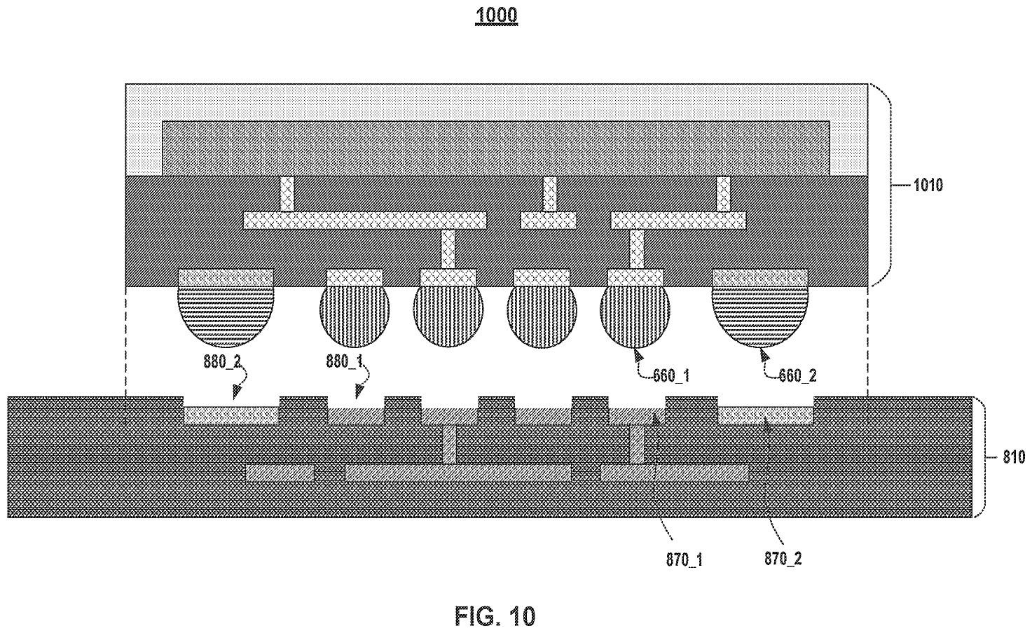

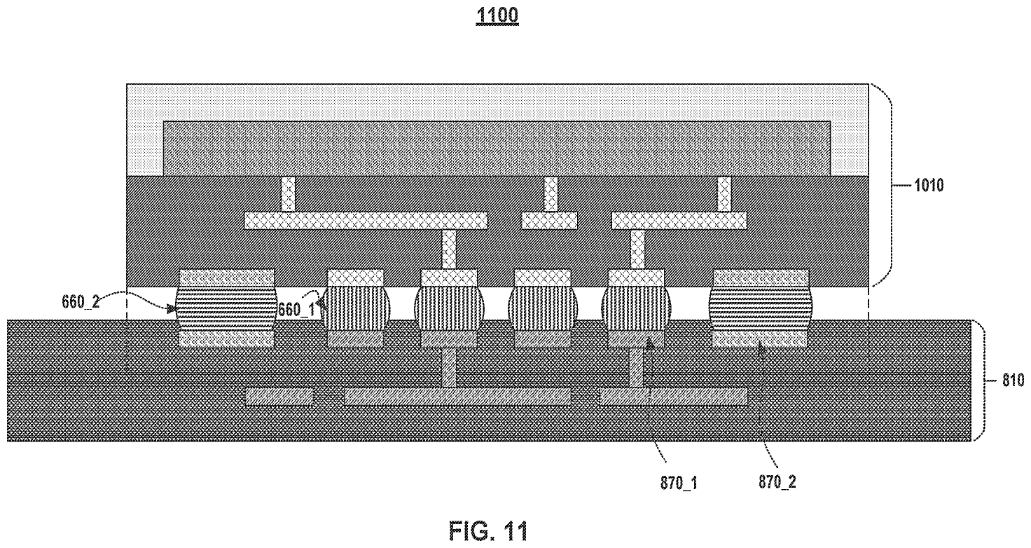

Referring back to FIG. 3, the method 300 can proceed to operation 340, in which the chip packing structure can be attached to the PCB. FIGS. 10 and 11 illustrate schematic diagrams in a perspective side view of a semiconductor structure 1000 and 1100 at certain stage of the operation 330 of the method 300 shown in FIG. 3, in accordance with some implementations of the present disclosure.

As shown in FIG. 10, the combined structure including the chip packing structure 1010 and the BAG 660 can be flipped over, and be aligned to the mounting region (e.g., 840 in FIG. 8) of the PCB 810. As such, each first solder ball 660_1 and/or each second solder ball 660_2 can be matched with a corresponding first ball opening 880_1 and/or second ball opening 880_2.

As shown in FIG. 11, the chip packing structure 1010 can be placed in the mounting region (e.g., 840 in FIG. 8) of the PCB 810, with each first solder ball 660_1 being in contact with a corresponding first contact pad 870_1, and each second solder ball 660_2 being in contact with a corresponding second contact pad 870_2. The assembly 1100 can then be heated, either in a reflow oven or by an infrared heater, melting the array of solder balls 660. Surface tension causes the molten solder balls 660 to hold the chip packing structure 1010 in alignment with the PCB 810, at the correct separation distance. After the solder balls 660 being cooled and solidified, soldered connections can be formed between the chip packing structure 1010 and the PCB 810.

The disclosed method for forming the enhanced interconnection ball grid array semiconductor structures can optimize the solder ball structure at the peripheral sides of the base substrate, and increase the mechanical strength of the interconnection ball structures to enhance the mechanical interconnections between chip packing structure to the PCB. Therefore, the mechanical interconnection failure of the semiconductor device in rapid temperature-changing environment can be reduced, the surface mount technology (SMT) yield rate can be increased, and the heat dissipation capability of the products can be improved.

The foregoing description of the specific implementations will so fully reveal the general nature of the present disclosure that others can, by applying knowledge within the skill of the art, readily modify and/or adapt, for various applications, such specific implementations, without undue experimentation, and without departing from the general concept of the present disclosure. Therefore, such adaptations and modifications are intended to be within the meaning and range of equivalents of the disclosed implementations, based on the disclosure and guidance presented herein. It is to be understood that the phraseology or terminology herein is for the purpose of description and not of limitation, such that the terminology or phraseology of the present specification is to be interpreted by the skilled artisan in light of the disclosure and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections can set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A semiconductor structure, comprising:
a printed circuit board;
a chip packing structure; and
a ball grid array connected between the printed circuit board and the chip packing structure, the ball grid array comprising:
first solder balls each having a first lateral size, and
second solder balls each having a second lateral size greater than the first lateral size, wherein the second solder balls are located at corners of the ball grid array, respectively.

2. The semiconductor structure of claim 1, wherein each second solder ball occupies at least a corner position of the ball grid array and laterally extends along a diagonal direction of the ball grid array.

3. The semiconductor structure of claim 1, wherein each second solder ball occupies at least a corner position of the ball grid array, and comprises:
a first portion laterally extending along a first direction along a row of the ball grid array; and
a second portion laterally extending along a second direction along a column of the ball grid array.

4. The semiconductor structure of claim 1, wherein each second solder ball partially surrounds a corner first solder ball of the ball grid array, and comprises:
a first portion laterally extending along a first direction along a row of the ball grid array; and
a second portion laterally extending along a second direction along a column of the ball grid array.

5. The semiconductor structure of claim 1, wherein:
the first solder balls are electrically connected between the printed circuit board and the chip packing structure; and
the second solder balls are electrically disconnected with the printed circuit board or the chip packing structure.

6. The semiconductor structure of claim 1, wherein the chip packing structure comprises:
a substrate;
at least one chip attached on a first surface of the substrate;
a conductive wiring structure embedded in the substrate and electrically connected with the at least one chip,
wherein the ball grid array is attached to a second surface of the substrate opposite to a first side, the first solder balls are electrically connected to the conductive wiring structure, and the second solder balls are electrically disconnected with the conductive wiring structure.

7. The semiconductor structure of claim 6, wherein the chip packing structure further comprises:
an array of ball pads on the second surface of the substrate, comprising:
first ball pads each having a first area and electrically connected to the conductive wiring structure, and
second ball pads each having a second area and electrically disconnected to the conductive wiring structure,
wherein the first area is less than the second area.

8. The semiconductor structure of claim 1, wherein a first material of the first solder balls is different from a second material of the second solder balls.

9. The semiconductor structure of claim 8, wherein:
the first material has a first mechanical strength and a first thermal expansion coefficient; and
the second material has a second mechanical strength greater than the first mechanical strength and a second thermal expansion coefficient less than the first thermal expansion coefficient.

10. A method of forming a semiconductor structure, comprising:
providing a chip packing structure, comprising:
attaching at least one chip on a first surface of a substrate, and
forming a ball grid array on a second surface of the substrate, the ball grid array comprising:
first solder balls each having a first lateral size, and
second solder balls each having a second lateral size greater than the first lateral size, wherein the second solder balls are located at corners of the ball grid array, respectively; and
attaching the chip packing structure to a printed circuit board, such that the ball grid array are connected between the chip packing structure and the printed circuit board.

11. The method of claim 10, wherein providing the chip packing structure comprises:
forming a conductive wiring structure embedded in the substrate; and
forming an array of ball pads on the second surface of the substrate, comprising:
first ball pads each having a first area and electrically connected to the conductive wiring structure, and
second ball pads each having a second area and electrically disconnected to the conductive wiring structure,
wherein the first area is less than the second area.

12. The method of claim 11, wherein providing the chip packing structure further comprises:
attaching the at least one chip attached on the first surface of the substrate;
wiring the at least one chip to the conductive wiring structure;
forming the ball grid array on the array of ball pads, comprising:
forming the first solder balls on the first ball pads, respectively; and
forming the second solder balls on the second ball pads, respectively.

13. The method of claim 12, wherein the first solder balls and the second solder balls are formed simultaneously in a same process.

14. The method of claim 12, further comprising:
forming an array of ball openings in a mounting region of the printed circuit board, comprising:
first ball openings each having a third area and exposing a contact pad electrically connected to a circuit of the printed circuit board, and
second ball openings each having a fourth area greater than the third area, wherein the second ball openings are located at corners of the mounting region, respectively.

15. The method of claim 14, wherein attaching the chip packing structure to the printed circuit board comprising:
aligning the chip packing structure to the mounting region of the printed circuit board;
attaching the chip packing structure to the mounting region of the printed circuit board, such that each first solder ball is located in a corresponding first ball opening, and each second solder ball is located in a corresponding second ball opening; and
sequentially heating and cooling the ball grid array, such that the chip packing structure is mechanically connected to the printed circuit board through the first solder balls and second solder balls.

16. A chip packing structure, comprising:
a substrate;
at least one chip attached on a first surface of the substrate;
a conductive wiring structure embedded in the substrate and electrically connected with the at least one chip; and
an array of ball pads on a second surface of the substrate opposite to the first surface, the array of ball pads comprising:
first ball pads each having a first area, and
second ball pads each having a second area greater than the first area, wherein the second ball pads are located at corners of the array of ball pads, respectively.

17. The chip packing structure of claim 16, wherein each second ball pad occupies at least a corner position of the array of ball pads and laterally extends along a diagonal direction of the array of ball pads.

18. The chip packing structure of claim 16, wherein each second ball pad occupies at least a corner position of the array of ball pads, and comprises:
a first portion laterally extending along a first direction along a row of the array of ball pads; and
a second portion laterally extending along a second direction along a column of the array of ball pads.

19. The chip packing structure of claim 16, wherein each second ball pad partially surrounds a corner first ball pad of the array of ball pads, and comprises:
a first portion laterally extending along a first direction along a row of the array of ball pads; and
a second portion laterally extending along a second direction along a column of the array of ball pads.

20. The chip packing structure of claim 16, wherein:
the first ball pads are electrically connected to the at least one chip through the conductive wiring structure; and
the second ball pads are electrically disconnected with the at least one chip and the conductive wiring structure.
